(19) United States
(12) Patent Application Publication
(10) Pub. No.: US 2009/0323288 A1
(43) Pub. Date: Dec. 31, 2009

(54) Heat sink slack storage and adaptive operation

(76) Inventor: Marc R. Bernard, Miramar, FL (US)

Correspondence Address: HAMILTON, BROOK, SMITH & REYNOLDS, P.C., 530 VIRGINIA ROAD, P.O. BOX 9133, CONCORD, MA, 01742-9133, US

(21) Appl. No.: 12/215,873

(22) Filed: Jun. 30, 2008

(51) Int. Cl. H05K 7/20

(52) U.S. Cl. 361/715

(57) ABSTRACT

Optical Network Terminals (ONTS) receive and transmit fiber optic data signals to a premises, such as a home or office, and generate heat, which must be dissipated. An outdoor installation may introduce additional heat loads over an indoor installation. An ONT designed for outdoor use may be overbuilt for indoor use and an ONT designed for indoor use may overheat in an outdoor location. Making separate ONTs for indoor and outdoor use is expensive. A heat sink according to an embodiment of the present invention is attachable to an exterior portion of an ONT and provides extra heat dissipation capability in hotter environments. Other embodiments place the heat sink in a fiber optic cable slack storage region. Other embodiments include interchangeable, different-capacity, heat sinks, and the ONT determines the capacity of the heat sink and operates at a power level appropriate for the heat sink capacity, i.e., thermal dissipation capability.

### BACKGROUND OF THE INVENTION

Optical Network Terminals (ONTS) are typically used to connect fiber optic cable from a telecommunications service provider to data lines, such as ethernet, telephone, and cable television, to a premises, such as an office or a home. The ONTs may be placed in many different locations at the premises, including an indoor placement and an outdoor placement.

Electrical components in the ONTs generate heat, which must be dissipated. An ONT may include on-board provisions for heat dissipation, such as vents in an exterior housing of the ONT. However, these on-board heat dissipation provisions may not be adequate for all environments. For example, the on-board heat dissipation provisions may be adequate for an ONT installed inside an air-conditioned premises, but may not be adequate for an outdoor installation in a region where temperatures regularly exceed 100° F. Designing an ONT with on-board heat dissipation provisions capable of handling the worst possible thermal conditions may be over-built and, as a result, overly expensive for easier thermal conditions. Likewise, designing and manufacturing different ONTs uniquely suited to different environments may be overly expensive by reducing economies of scale.

### SUMMARY OF THE INVENTION

An example embodiment of the present invention includes an optionally installed heat sink, external from an Optical Network Terminal (ONT), configured to transfer heat away from the ONT electronics. The heat sink may be installed on the ONT when the ONT is used in hotter environments. In some embodiments, the heat sink may be used to arrange stored slack fiber optic cable.

In some embodiments, the heat sink is one of several different capacities of heat sinks. The ONT may automatically detect the capacities of the heat sink and automatically operate at a power level that generates heat at a rate that the heat sink is capable of dissipating.

### BRIEF DESCRIPTION OF THE DRAWINGS

The foregoing will be apparent from the following more particular description of example embodiments of the invention, as illustrated in the accompanying drawings in which like reference characters refer to the same parts throughout the different views. The drawings are not necessarily to scale, emphasis instead being placed upon illustrating embodiments of the present invention.

FIG. 1 is a network diagram showing typical configurations for an Optical Network Terminal (ONT) with an external heat sink according to an example embodiment of the present invention at a premises and connected to an external data network;

FIG. 2 is a close-up diagram showing the parts of an ONT;

FIG. 3 is a bottom-view diagram of an ONT base with an external heat sink installed according to an example embodiment of the present invention;

FIG. 4 is a side-view diagram of an ONT on a base with an external heat sink installed according to an example embodiment of the present invention;

FIGS. 5A and 5B are example flow diagrams of procedures performed by an ONT to identify whether an external heat sink or type of heat sink is connected to the ONT;

FIG. 6A is a side-view schematic diagram of a base with a door blocking airflow from a vent according to an example embodiment of the present invention;

FIG. 6B is a side-view schematic diagram of the base of FIG. 6A with the door opened by a heat sink according to an example embodiment of the present invention;

FIG. 7 is a schematic diagram of a series of ONTs with external heat sinks connected via a heat transfer conduit according to an example embodiment of the present invention;

FIG. 8 is a schematic diagram of a series of ONTs with external heat sinks connected via heat transfer conduits to an active cooling device according to an example embodiment of the present invention; and

FIG. 9 is a schematic diagram of an ONT mounted to an outdoor surface of a wall and connected to a heat sink mounted to an interior surface of the wall according to an example embodiment of the present invention.

### DETAILED DESCRIPTION OF THE INVENTION

A description of example embodiments of the invention follows.

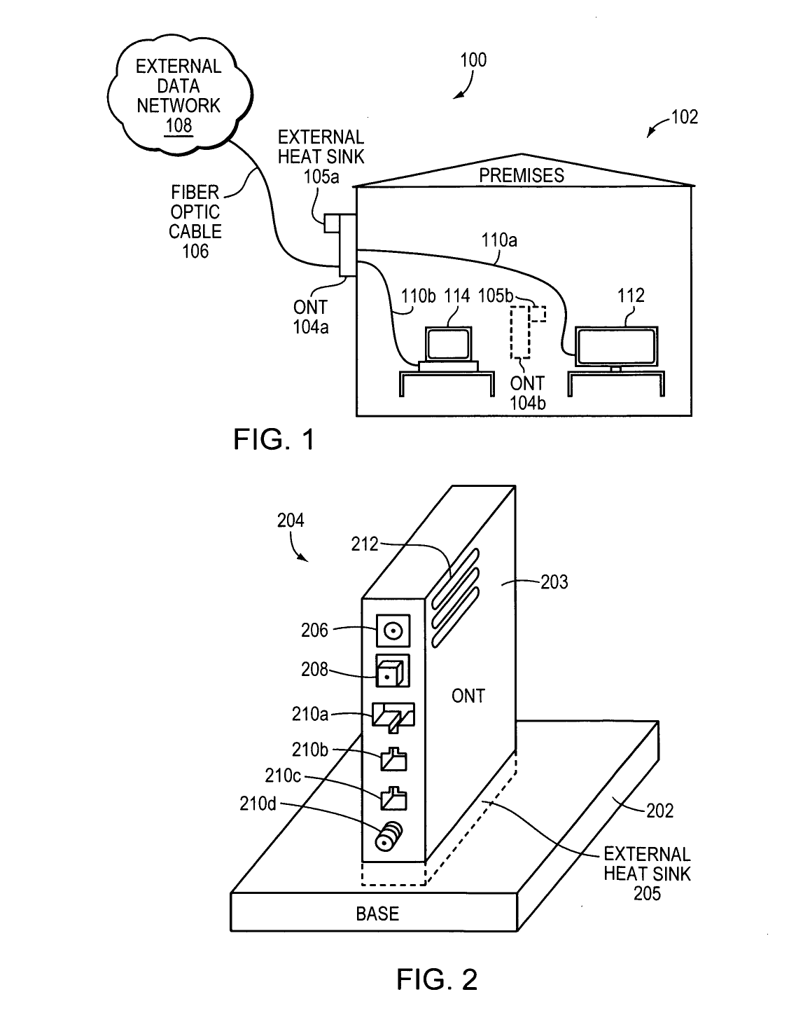

FIG. 1 shows a typical configuration 100 of a network to a premises 102. FIG. 1 shows premises 102 as a house. It should be understood that the premises 102 may be any type of structure, such as an office building or a factory, for example. In this configuration, an Optical Network Terminal (ONT) 105a, 105b is attached to the side of the premises 102. The ONT 104a is in communication with an external data network 108 by a fiber optic cable 106. An alternative placement for the ONT 104b is shown inside the house 102. The alternatively-placed ONT 104b is still connected to a fiber optic cable (not shown). The ONT 104a or 104b communicates with the external network 108, carrying data to various devices within the premises 102, such as a computer 114 or a television 112, for example. The ONTs 104a, 104b each include a respective, externally mounted, heat sink 105a, 105b according to an embodiment of the present invention.

FIG. 2 shows an ONT for use within a premises. The ONT 204 has various connector ports for power 206, for the fiber optic cable 208, and for various connections such as ethernet 210a, telephone connections 210b, 210c, and coaxial cable 210d. The ONT 204 is supported by a base 202. The ONT 204 also has vents 212 on its side configured to release heat generated by normal operations of the electrical components within the ONT 204. The ONT 204 includes electronics (not shown), and an external heat sink 205, according to an embodiment of the present invention, is connected to the electronics in a manner providing thermal communication through an enclosure 203 of the ONT 204 to enable the external heat sink 205 to provide cooling for the electronics. It should be understood that the electronics are an example of possible heat sources that may be within the enclosure 203 that are in thermal communication with the external heat sink 205.

The ONT may be capable of dissipating a certain amount of heat via internal cooling structures, such as heat sinks or exchangers, cooling fins, etc. (not shown), and releasing the heat through vents 212. The vents 212 may or may not be sized for all possible placements of the ONT 204. For example, if the ONT is placed inside of a house where the climate is controlled, then a minimal amount of cooling may be necessary. Alternatively, if the ONT is placed in a hot outdoor environment, then a significantly higher amount of cooling is necessary. ONTs are either specifically designed for a specific application, e.g., indoor vs. outdoor vs. extremely hot outdoor location, or are overbuilt to handle the worst possible environments, which substantially increases the cost of the ONTs.

In some embodiments, the ONT 204 enclosure 203 is made of a plastic material or other material that is a poor thermal conductor. Therefore, the enclosure 203 may have ports, holes, or other structural features that enable the external heat sink to connect thermally to the heat source within the enclosure 203.

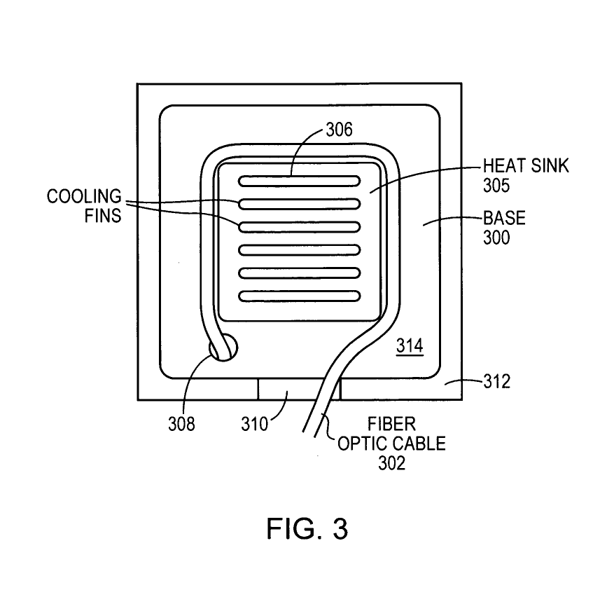

FIG. 3 shows an embodiment of the present invention with a base 300 having walls 312 defining a cavity 314. In the center of the cavity 314 resides a heat sink 305. The heat sink 305 has cooling fins 306. A fiber optic cable 302 enters through hole 310 and wall 312 and wraps around the heat sink 305, once as shown or multiple times, before exiting through hole 308 in the top of the base 300. The heat sink 305 is in thermal contact or thermal communication with the electrical components (not shown) in the ONT mounted on top of the base 300. The heat sink removes additional heat from those electrical components, thereby allowing the electrical components to be operated at a higher power level than they would in the absence of the heat sink 305.

It should be understood that the heat sink 305, optionally a heat exchanger, can be coupled to the electrical components, i.e., heat source, through the enclosure (not shown) of the ONT enclosing the electrical components at locations other than from within the cavity 314 of the base 300, such as on a rear side of the enclosure. Because the heat sink 305 may be thermally hot, a guard (not shown) may be employed to protect users.

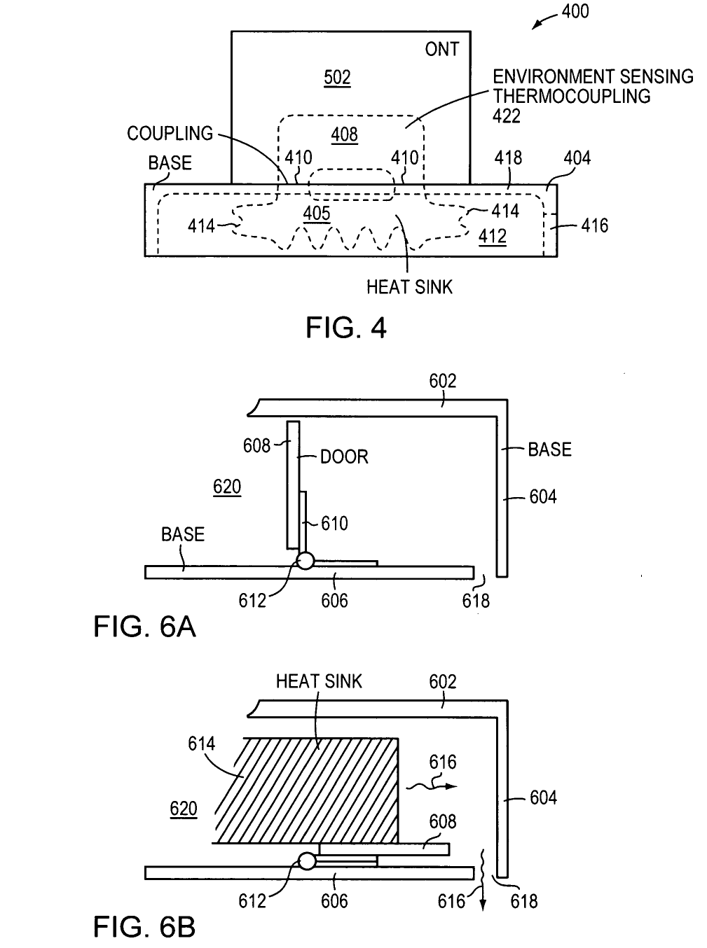

FIG. 4 is a side view of an embodiment of the present invention showing an ONT 402 mounted on top of a base 404. The base has a cavity 412 that is partially filled by a heat sink 405. The heat sink 405 is in contact with the electrical components 408 inside the ONT 402. The example heat sink 405 interfaces with the electrical components 408 at two contact points 410. Typically, the interface between the heat sink 405 and the electrical components or heat source 408 is conductive contact. In other words, portions of the electrical components 408 which are generating heat are in direct physical contact with a portion of the heat sink 405 such that heat is transferred through conductance from the heat source 408 to the heat sink 405. The heat sink 405 draws heat energy away from the electrical components 408 and dissipates that heat from the surrounding air.

The heat sink 405 may include a groove 414 around its perimeter to arrange stored slack cable, e.g., a fiber optic cable (not shown), that enters through hole 416 in the side of the base 404 and exits through a hole 418 in the top of the base 404. By arranging stored slack cable, such as the fiber optic cable 302 of FIG. 3, the heat sink 405 functions in a way it is not normally used in addition to functioning as a heat sink. Moreover, the heat sink 405 may be configured to provide the arranging as a function of a minimum bend radius parameter of the stored slack cable. Other forms of arranging include holding the cable within a compartment (not shown) of the heat sink 405, providing a spool (not shown) about which the cable is wound, and so forth.

The heat sink 405 may be one of several capacities of heat sinks. The term “capacity” as it relates to heat sinks is intended to mean the heat dissipation capability of the heat sink. Heat dissipation capability is only partly related to the physical size, i.e., mass, of the heat sink. In transient heat transfer circumstances, such as when both a heat source and a heat sink are starting from a cold/ambient temperature and the heat source is warming towards its operating temperature, a physically larger heat sink may be able to absorb more heat from the warming heat source. In steady state heat transfer circumstances, when both the heat source and heat sink have reached stable operating temperatures, the heat dissipation capability is dependent on heat transfer to a surrounding medium, which is typically air. Heat transfer to a surrounding medium, such as air, may be enhanced by adding, for example, “fins” of material, i.e., cooling fins, that increase the surface area of the heat sink in contact with the surrounding medium. These fins do not substantially increase the physical size, i.e., mass, of the heat sink. Hence, the term “capacity” as it relates to heat sinks means the capability of a heat sink to remove and dissipate heat from a heat source. Thus, a heat sink with more heat dissipation capability has more capacity than a heat sink with less heat dissipation capability. Embodiments of ONTs according to the present invention may be configured to be attached to various external heat sinks of different capacities.

FIG. 4 is an example of the present invention that shows an ONT 402 and base 404; electronics 408 in the ONT 402 and heat sink 406 in the base 404 are connected via contact points 410. The contact points' 410 configuration, e.g., size and placement, may be common to all ONTs and heat sink sizes such that different sized heat sinks may be interchangeably connected to the ONTs.

Embodiments of the ONTs, such as the ONT shown in FIG. 4, include structure and logic (not shown), such as software, to determine automatically the capacity of the heat sink attached to contact points 410 and, in turn, provide information or control used in the ONT's operating the electronics 408, accordingly. The interface used to determine the capacity of the heat sink may be mechanical, electrical, or a combination thereof, for example. For example, each different capacity heat sink may include a uniquely shaped or sized pin (not shown) configured to fit into a receptacle (not shown) at a contact point 410 of the ONT 402. The example receptacle is enabled to determine the shape or size of the pin to determine the capacity of the heat sink. The determined capacity information may then be provided to the electronics 408 to determine an operating power level at which the electronics may be operated In alternative embodiments, the interface used to determine the capacity of the heat sink may be electrical. For example, the means may include electrical contacts (not shown) on the electronics 408 and the heat sink 405 such that when the heat sink 405 is connected to the electronics 408, an electrical circuit is closed. A resistor or capacitor or other electrical component may be associated with the electrical contacts (not shown) on the heat sink. The resistor, capacitor, or other electrical component may have different properties for each size of heat sink such that the ONT electronics 408 can read identify the capacity of the heat sink 406 by detecting the electrical properties of the closed circuit.

The electronics 408 may also employ an environment sensing thermocouple 422 to supplement its knowledge of the capacity of the heat sink 406. For example, if the electronics 408 via the environment sensing thermocouple 422 detects a temperature (e.g., cold) suitable to operate itself at a power level beyond the capacity of the heat sink 406, the electronics 408 can do so. It should be understood that the thermocouple 422 is an example of an environment sensor and that other sensors, such as a sensor for determining airflow across the heat sink 406, may also or alternatively be employed. It should also be understood that traditional or custom measurements and calculations to determine effective capacity of the heat sink 406 may be employed by the electronics 408.

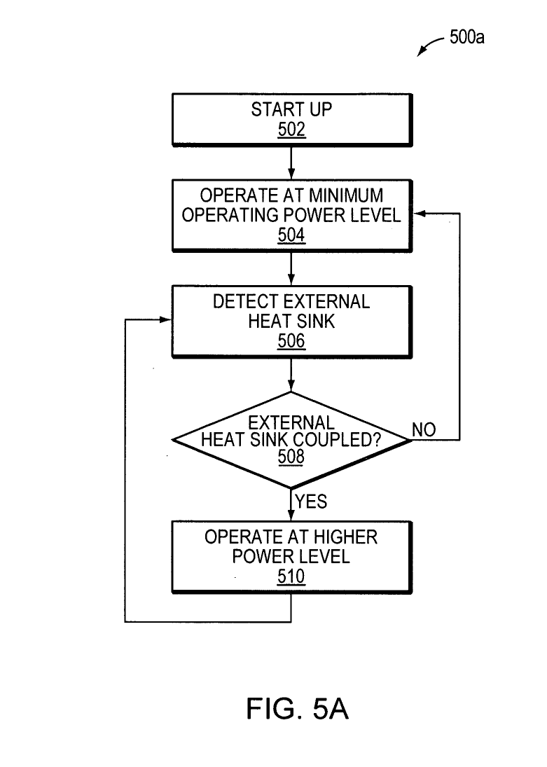

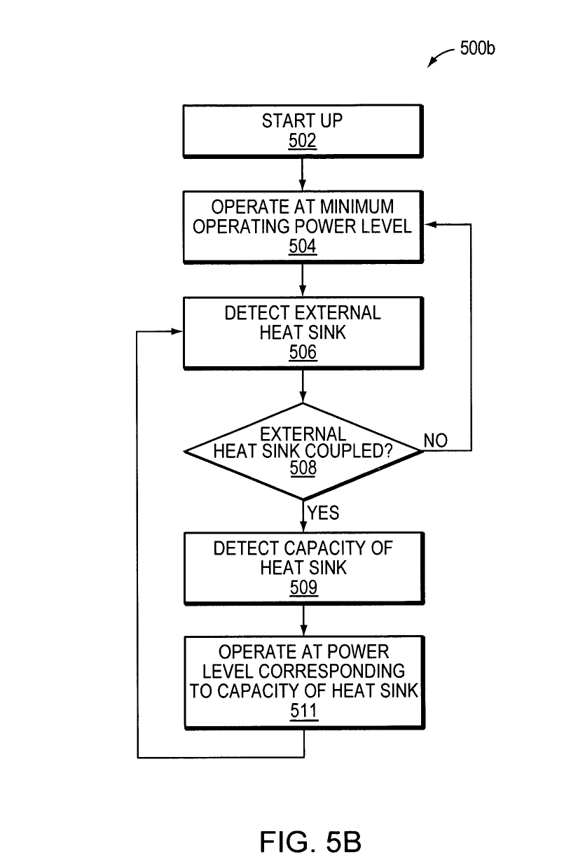

FIG. 5A is an example flow diagram 500a describing how an ONT according to an embodiment of the present invention may operate. Following startup 502, the ONT establishes operation at a minimum operating power level 504. At the minimum operating power level 504, the ONT electronics generate a minimum amount of heat that the ONT is capable of dissipating without any external heat sink. After establishing minimum operating power 504, the ONT determines whether an external heat sink is attached 506. The ONT continues operating at minimum power levels 504 if no external heat sink is detected 508. If the ONT detects an external heat sink, then the ONT operates at a higher power level 510, i.e., offer more or enhanced data services, thereby generating additional heat that the external heat sink is capable of dissipating. After establishing the higher operating level, the ONT continuously or periodically returns to detect the external heat sink 506. If the heat sink is removed, accidentally or on purpose, then the ONT reverts to the minimum operating power level 504.

FIG. 5B is an example flow diagram 506 describing how an ONT according to an embodiment of the present invention may operate in the presence of a heat sink of a certain capacity out of many different heat sink capacities. Following startup 502, the heat sink establishes operation at a minimum operating power level 504. At the minimum operating power level 504, the ONT electronics generate a minimum amount of heat that the ONT is capable of dissipating without any external heat sink. After establishing minimum operating power at 504, the ONT determines whether an external heat sink is attached 506. The ONT continues operating at minimum power levels 504 if no external heat sink is detected 508. If the ONT detects an external heat sink, then the ONT determines the capacity of the heat sink 509. The ONT operates at a higher power level 511, i.e., offer more or enhanced data services, thereby generating additional heat, matching the capacity of the external heat sink. After establishing the higher operating level, the ONT continuously or periodically returns to detect the external heat sink 506. If the heat sink is removed, accidentally or on purpose, then the ONT reverts to the minimum operating power level 504. Likewise, if the heat sink is swapped for a different heat sink with a different capacity, the ONT changes operating power level to match the capacity of the different heat sink 509, 511.

FIGS. 6A and 6B show an embodiment of a base with at least one vent 618, which, in some embodiments, may only open in the presence of a heat sink 614. As discussed earlier, a heat sink's capability to dissipate heat is dependent on its ability to move heat to a surrounding medium, such as air. Air circulation further improves heat transfer from a heat sink to air. Thus, vents on a base for an ONT improve heat dissipation capability of a heat sink installed in the base as described above. However, vents may not always be employed as they may introduce dust and moisture. The partially-depicted base shown in FIGS. 6A and 6B, defined by top 602, bottom 606, and wall 604, has a door 608 mounted by a hinge 610 to the bottom 606. The hinge 610 may include a spring 612 that maintains the door 608 in a closed position, blocking air that enters through vent 618 from passing into an interior portion 620 of the base. When a heat sink 614 is installed in the base, as shown in FIG. 6B, the door 608 is pushed down, creating a path for hot air 616 to escape through the vent 618 and for cool air (not shown) to enter through the vent 618.

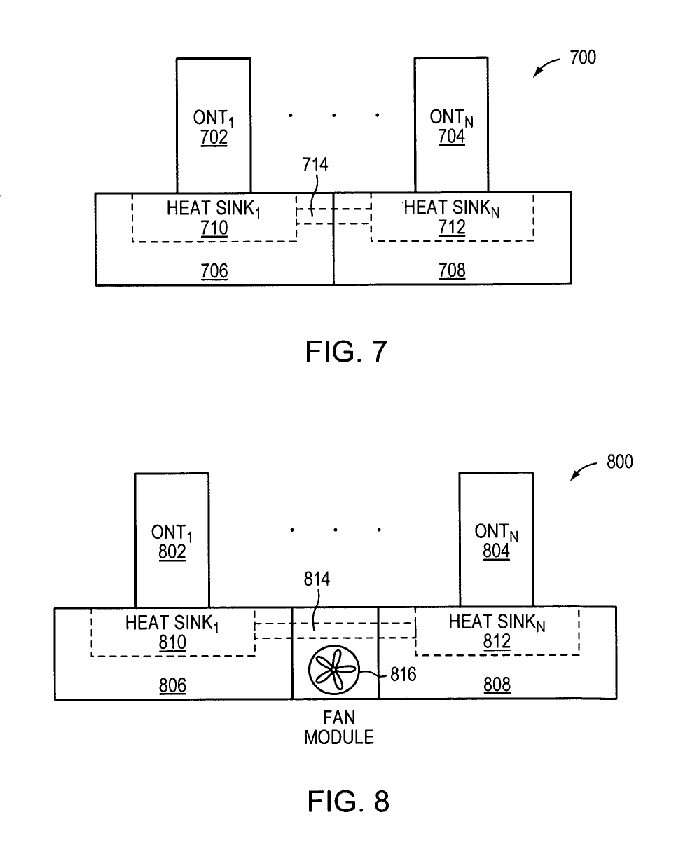

FIG. 7 shows an embodiment in which two or more ONTs 702, 704 and their respective bases 706, 708 are linked together. Each base 706, 708 includes a heat sink 710, 712. The heat sinks 710, 712 may be connected by a heat transfer conduit 714, typically a channel of heat-conducting metal, such that a hotter heat sink may send some heat to a cooler heat sink. Such a configuration may be advantageous where a single premises uses multiple ONTs. At any given time, one particular ONT, ONT 702 for example, may experience higher usage than the remaining ONTs (ONT 704, for example). In such a case, a first ONT 702 generates more heat than a second ONT 704, and a first heat sink 710 corresponding to the first ONT 702 has to dissipate more heat than a second heat sink 712 corresponding to the second ONT 704. In this case, as the first heat sink 710 becomes hotter than the second heat sink 712, some heat energy flows via the conduit 714 from the first heat sink 710 to the second heat sink 712. By any of the mechanisms described above, the ONT(s) may detect the presence of additional heat sinks and adjust behavior accordingly, e.g., operate at a higher or lower power level, enable or disable video services, and so forth.

FIG. 8 shows an embodiment in which one or more ONTs 802, 804 and their respective bases 806, 808 are linked to an active cooling device 816, such as a fan. As in FIG. 7, heat sinks 810, 812 in bases 806, 806, respectively, are connected to a heat transfer conduit 814. The heat transfer conduit 814 is also connected to an active cooling device, such as the fan 816. In the case of an active cooling mechanism, the heat transfer conduit may be an air plenum through which air is blown to interact with the heat sinks 810, 812. The fan 816 or other cooling device, such as a forced air heat exchanger, is capable of dissipating more heat than the heat sinks 810, 812. The fan 816 may be active at all times or may be activated only when ONTs 802, 804 are operating above a threshold power level. A person having ordinary skill in the art understands that the active cooling device may be attached to a single ONT. By any of the mechanisms described above, the ONT may detect the presence of an active cooling device and adjust its behavior accordingly, i.e., operate at a higher power level.

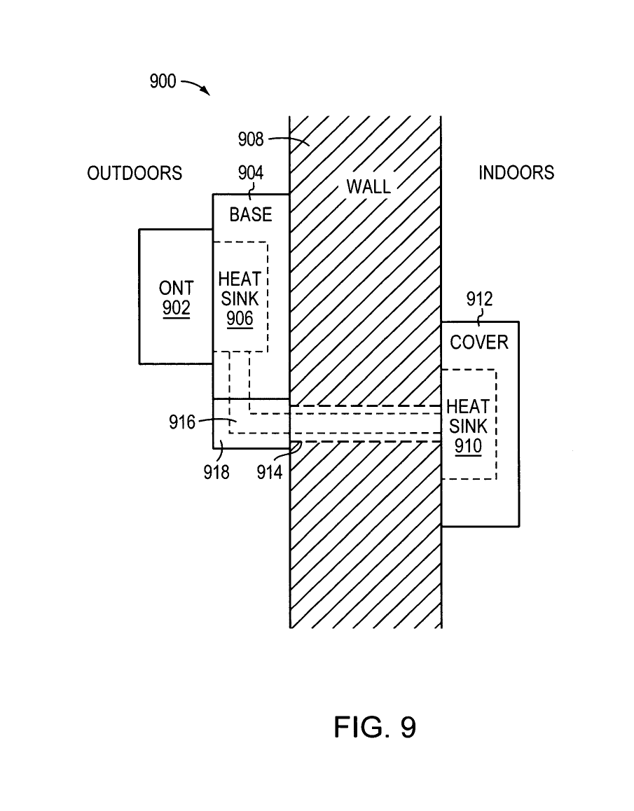

FIG. 9 shows an embodiment 900 in which a heat sink 910 is connected to an ONT 902 via a heat transfer conduit 916 such that the heat sink 910 is located in a different environment from the ONT 902. In FIG. 9, the ONT 902 and base 904 are mounted to a wall 908 outdoors. The base 904 optionally may carry a heat sink 906. The base 904 also carries a portion of heat transfer conduit 916, which passes through a hole 914 in the wall 908 to a second heat sink 910 located on an indoors side of the wall 908. As shown in FIG. 9, the heat transfer conduit 916 is partially covered by a secondary cover 918. Also, indoors, the heat sink 910 may optionally be covered by a cover 912. By moving the heat sink 910 to an indoor surface of the wall 908, the heat sink 910 may be exposed to cooler air temperatures than the heat sink 906 on the exterior surface of the wall 908. The lower air temperatures enable greater heat dissipation. By any of the mechanisms described above, the ONT 902 may detect the presence of the heat sink in the indoors environment and adjust its behavior accordingly, e.g., operate at a higher power level.

It should be understood that the ONT 902 includes logic, such as logic implementing the example procedures of FIGS. 5A and 5B, in the form of mechanical, electrical, firmware, or software to adjust behavior of the ONT 902 in the presence of various types or capacities of heat sinks. In the case of software, it should be understood that the processor may be any language suitable to adjust behavior of the ONT and optionally independent of or integrated into a general purpose or application-specific electronics within the ONT 902 used to support traffic operations. The software may be stored on any form of processor readable media and loaded and executed by a processor as understood in the art. The software may self-recognize presence or capacity of a heat sink attached to the ONT or by triggered by some event, such as closure or opening of a mechanical switch caused by attachment or detachment of a heat sink or provisioning by a management node elsewhere in a network to which the ONT 902 is in communication.

While this invention has been particularly shown and described with references to example embodiments thereof, it will be understood by those skilled in the art that various changes in form and details may be made therein without departing from the scope of the invention encompassed by the appended claims.

What is claimed is:

1. An electronics assembly, comprising:
a heat source;
a heat sink; and
an enclosure configured to enclose the heat source and enable heat transfer from the heat source to the heat sink, the heat sink configured to be coupled externally to the enclosure in thermal communication with the heat sink and configured to arrange stored slack cable coupled to the electronics assembly.

2. The electronics assembly of claim 1 further comprising a second enclosure configured to at least partially enclose the heat sink.

3. The electronics assembly of claim 2 wherein the second enclosure is further configured to support the first enclosure.

4. The electronics assembly of claim 1 wherein the heat sink is configured to have slack cable wound around it.

5. The electronics assembly of claim 1 wherein the heat source is configured to detect the presence of the heat sink and to change behavior in the presence of the heat sink compared to its absence.

6. The electronics assembly of claim 5 wherein the heat source is configured to be controlled to generate more heat in the presence of the heat sink compared to the heat generated in the absence of the heat sink.

7. The electronics assembly of claim 1 wherein the heat sink is one of at least two different capacities of heat sinks; and
wherein the heat source is configured to detect the presence and capacity of the heat sink and change its behavior based on the capacity of the heat sink.

8. The electronics assembly of claim 7 wherein the heat source is configured to generate more heat in the presence of a larger-capacity heat sink compared to the heat generated in the presence of a smaller-capacity heat sink.

9. The electronics assembly of claim 1 wherein the heat sink is a first heat sink; and
further comprising a second heat sink, wherein the second heat sink is connected to the first heat sink via a heat transfer conduit.

10. The electronics assembly of claim 1 further comprising an active cooling device in thermal communication with the heat sink.

11. The electronics assembly of claim 1 wherein the heat sink is located in a different temperature environment from the heat source.

12. A method of dissipating heat from an electronics assembly, comprising:
enclosing a heat source generating heat in an enclosure;
operating the heat source at a power level within the enclosure in a manner generating heat; and
transferring heat from a heat source internal to the enclosure to a heat sink external from the enclosure, the heat sink configured to dissipate the generated heat, and simultaneously to arrange on a portion of the heat sink stored slack cable coupled to the electronics assembly.

13. The method of claim 12 wherein transferring the generated heat to a heat sink external to the enclosure includes transferring the generated heat to a heat sink at least partially enclosed in a second enclosure.

14. The method of claim 13 further including supporting the second enclosure with the first enclosure.

15. The method of claim 12 wherein simultaneously arranging storing slack cable on a portion of the heat sink includes supporting the slack cable in a wound arrangement around a portion of the heat sink.

16. The method of claim 12 further comprising detecting the presence of the heat sink and changing the behavior of the heat source in the presence of the heat sink compared to its absence.

17. The method of claim 16 wherein changing the behavior of the heat source includes operating the heat source at a higher power level in the presence of the heat sink compared to a lower power level in the absence of the heat sink.

18. The method of claim 12 further comprising detecting the presence and capacity of the heat sink and changing the behavior of the heat source based on the capacity of the heat sink.

19. The method of claim 18 wherein changing behavior of the electronics includes operating the heat source at a higher power level in the presence of a larger-capacity heat sink compared to a lower power level in the presence of a smaller-capacity heat sink.

20. The method of claim 12 further comprising transferring a portion of the generated heat from the heat sink to a second heat sink via a heat transfer conduit.

21. The method of claim 12 further comprising dissipating at least a portion of the generated heat to or in combination with an active cooling device.

22. The method of claim 12 wherein transferring the generated heat to a heat sink external from the enclosure includes transferring the generated heat to a heat sink located in a thermally different environment from the heat source.

23. An electronics assembly, comprising:
a heat sink of a certain capacity; and
a heat source coupled to the heat sink and configured to identify the capacity of the heat sink and change its behavior based on the identified capacity.

24. The electronics assembly of claim 23 wherein the heat sink is one of at least two different capacities of heat sinks; and
wherein the heat source is configured to generate more heat in the presence of a larger-capacity heat sink compared to the heat generated in the presence of a smaller-capacity heat sink.

25. The electronics assembly of claim 23 further comprising a coupler, the coupler including a first coupling component on the heat source and a second coupling component on the heat sink, the coupler configured to provide identification of the capacity of the heat sink to the heat source in a state in which the first coupling component of the coupler and the second coupling component of the coupler are coupled.

26. The electronics assembly of claim 25 wherein the coupler is a mechanical connection configured to identify the capacity of the heat sink to a logic element configured to effect a change in behavior of the ONT based on the capacity.

27. The electronics assembly of claim 25 wherein the coupler is an electrical connection and includes at least one electrical element configured to identify the capacity of the heat sink to a logic element configured to effect a change in behavior of the ONT based on the capacity.

28. The electronics assembly of claim 23 further comprising an enclosure configured to enclose the heat source and enable heat transfer from the heat source to the heat sink externally connected to the heat sink.

29. The electronics assembly of claim 23 wherein the heat sink of a certain capacity is a first heat sink of a first capacity;
further comprising a second heat sink of a second capacity, wherein the second heat sink is connected to the first heat sink via a heat transfer conduit; and
wherein the heat source is further configured to identify the second capacity of the second heat sink and change its behavior based on the identified second capacity of the second heat sink.

30. The electronics assembly of claim 23 further comprising an active cooling device connected to the heat sink via a heat transfer conduit; and
wherein the heat source is further configured to identify the active cooling device connected to the heat sink via the heat transfer conduit and change its behavior based on the identified active cooling device.

31. The electronics assembly of claim 23 wherein the heat sink is located in a different temperature environment from the heat source; and
wherein the heat source is further configured to identify the different temperature environment of the heat sink and change its behavior based on the different temperature environment of the heat sink.

32. A method of dissipating heat from an electronics enclosure, comprising:
detecting the presence and capacity of a heat sink coupled to a heat source within a first enclosure;
operating the heat source at a power level matching the capacity of the detected heat sink; and
transferring the generated heat to the detected heat sink.

33. The method of claim 32 wherein operating the electronics at a power level matching the capacity of the detected heat sink includes operating the electronics at a higher power level in the presence of a larger-capacity heat sink compared to a lower power level in the presence of a smaller-capacity heat sink.

34. The method of claim 32 wherein detecting the presence and capacity of a heat sink includes reading an identifier associated with the heat sink in a state in which the heat sink is coupled to the heat source.

35. The method of claim 34 wherein coupling the identification structure includes mechanically, electrically, electromagnetically, acoustically, or optically reading the identifier.

36. The method of claim 32 wherein transferring the generated heat to the detected heat sink includes transferring the generated heat through a enclosure, the electronics being inside the enclosure and the heat sink being external from the enclosure.

37. The method of claim 32 further comprising transferring a portion of the generated heat from the heat sink to a second heat sink via a heat transfer conduit.

38. The method of claim 32 further comprising dissipating at least a portion of the generated heat to or in combination with an active cooling device.

39. The method of claim 32 further including identifying a thermal environment of the heat sink and changing the operating of the heat source based on the thermal environment identified.
